(19) United States
(12) Patent Application Publication
(10) Pub. No.: US 2025/0320605 A1
(43) Pub. Date: Oct. 16, 2025

(54) VAPOR DEPOSITION CHAMBER WITH BLOCKER PLATE

(71) Applicant: Applied Materials, Inc., Santa Clara, CA (US)

(72) Inventors: Shashidhara Patel H B, Bangalore (IN); Rakesh Ramadas, San Jose, CA (US); Muhannad Mustafa, Milpitas, CA (US); Amit Sahu, Bangalore (IN); Sanjeev Baluja, Campbell, CA (US); Janisht Golcha, San Francisco, CA (US)

(73) Assignee: Applied Materials, Inc., Santa Clara, CA (US)

(21) Appl. No.: 18/634,388

(22) Filed: Apr. 12, 2024

(51) Int. Cl. C23C 16/46; C23C 16/455; C23C 16/458

(52) U.S. Cl. CPC C23C 16/46; C23C 16/45544; C23C 16/45565; C23C 16/4583

(57) ABSTRACT

Thermal bases for gas distribution assemblies, gas distribution assemblies incorporating the thermal bases, and process chambers incorporating the gas distribution assemblies are described. The thermal bases have an annular slit formed in the front surface of the thermal base. The annular slit forms a boundary between the inner portion and outer portion of the thermal base. Processing methods using the thermal base for temperature uniformity improvement are also described.

### TECHNICAL FIELD

Embodiments of the disclosure generally relate to electronic devices and methods of forming electronic devices. In particular, embodiments of the disclosure relate to etching of molybdenum oxides with non-chlorine reactants.

### BACKGROUND

The electronic device industry and the semiconductor industry continue to strive for larger production yields while increasing the uniformity of layers deposited on substrates having increasingly larger surface areas. These same factors in combination with new materials also provide higher integration of circuits per unit area on the substrate.

As the dimensions of devices continue to shrink, tolerances for individual layer non-uniformity decreases. Existing vapor deposition chambers used for chemical vapor deposition (CVD) and atomic layer deposition (ALD) incorporate a funnel-shaped lid and a showerhead with ports that introduce chemical precursors into a process area surrounded by an open liner. In this prior art design, the showerhead is heated primarily by the proximity to the substrate support, with a smaller contribution from the heater on the funnel lid. This results in a system with little to no control over thermal distribution. Conventional process chamber hardware has high thermal non-uniformity >5% and high temp fluctuations on the lid.

Additionally, the thermal non-uniformity causes deflection of the showerhead and thermal base. This is believed to be due to low component thickness and small thermal contacts.

Therefore, there is an ongoing need in the art for apparatus and methods to improve thermal uniformity of the showerhead and/or thermal base to improve deposition uniformity.

### SUMMARY OF THE CLAIMS

One or more embodiments of the disclosure are directed to a thermal base for a gas distribution assembly. The thermal base has a back surface and a front surface defining a thickness of the thermal base. The front surface has an inner portion and an outer portion. A cylindrical opening extends through the thickness of the thermal base. An annular slit is formed in the front surface of the thermal base. The annular slit forms a boundary between the inner portion and outer portion. The annular slit has a width and depth measured from the front surface. The thermal base is configured to attenuate thermal transfer from the inner portion to the outer portion and maintain thermal uniformity in the gas distribution assembly.

Additional embodiments of the disclosure are directed to a gas distribution assembly for a semiconductor manufacturing processing chamber. The gas distribution assembly comprises a thermal base, a blocker plate, a showerhead, an insulator plate and at least one thermal contact. The thermal base has a back surface and a front surface defining a thickness of the thermal base. The front surface has an inner portion and an outer portion. A cylindrical opening extends through the thickness of the thermal base. An annular slit is formed in the front surface of the thermal base. The annular slit forms a boundary between the inner portion and outer portion. The annular slit has a width and depth measured from the front surface. The blocker plate has a back surface and a front surface defining a thickness of the blocker plate. The blocker plate is positioned so that an outer portion of the back surface of the blocker plate contacts the inner portion of the front surface of the thermal base. The blocker plate has a plurality of apertures extending through the thickness of the blocker plate. The showerhead has a back surface and a front surface defining a thickness of the showerhead. The showerhead is positioned so that an outer portion of the back surface of the showerhead contacts an outer portion of the front surface of the blocker plate. The insulator plate is around an outer peripheral edge of the blocker plate. The insulator plate has a back surface in contact with the outer portion of the front surface of the thermal base. The at least one thermal contact extends through the thickness of the outer portion of the thermal base and extends through the thickness of the insulator plate.

Further embodiments of the disclosure are directed to a processing method including: heating a substrate support pedestal positioned within an interior volume of a semiconductor manufacturing processing chamber to a temperature greater than standard room temperature. The substrate support pedestal heats a showerhead positioned adjacent to and spaced from the substrate support pedestal. Radiative heat transfer from the showerhead to a lid plate of the processing chamber is prevented.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

The shading used in the Figures is for descriptive purposes only and should not be taken as referring to a particular material of construction. The cross-hatching patterns are solely chosen to help illustrate the different components and unless otherwise noted, the various materials of construction of the different components can be the same or different.

FIG. 1 illustrates a prior art embodiment of a semiconductor manufacturing processing chamber 100;

FIG. 2 shows a portion of the semiconductor manufacturing processing chamber 100 of FIG. 1 where the gas distribution assembly, lid plate and sidewall meet;

FIG. 3 illustrates a bottom isometric cross-section view of a thermal base according to one or more embodiments of the disclosure;

FIG. 4 shows a cross-sectional view of a semiconductor manufacturing processing chamber according to one or more embodiments of the disclosure; and

FIG. 5 shows an expanded view of a portion of the semiconductor manufacturing processing chamber of FIG. 4 illustrating the thermal path according to one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

“Atomic layer deposition” or “cyclical deposition” as used herein refers to a process comprising the sequential exposure of two or more reactive compounds to deposit a layer of material on a substrate surface. “Atomic layer deposition” or “cyclical deposition” as used herein refers to a process comprising the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas. The gas curtain can be any suitable gas separation arrangement known to the skilled artisan. For example, in some embodiments of a spatial ALD process chamber, a gas curtain is formed by a combination of purge gas ports and vacuum ports to maintain separation between the reactive gases to prevent gas-phase reactions. In some embodiments of a spatial ALD process chamber, separate process stations are configured to form a mini-process environment within each station.

As used in this specification and the appended claims, the terms “reactive compound”, “reactive gas”, “reactive species”, “precursor”, “process gas” and the like are used interchangeably to mean a substance with a species capable of reacting with the substrate surface or material on the substrate surface in a surface reaction (e.g., chemisorption, oxidation, reduction, cycloaddition). The substrate, or portion of the substrate, is exposed sequentially to the two or more reactive compounds which are introduced into a reaction zone of a processing chamber.

The term “about” as used herein means approximately or nearly and in the context of a numerical value or range set forth means a variation of ±15% or less, of the numerical value. For example, a value differing by ±14%, ±10%, ±5%, ±2%, ±1%, ±0.5%, or ±0.1% would satisfy the definition of “about.”

Spatially relative terms, such as “beneath,” “below,” “lower,” “above,” “upper” and the like, may be used herein for ease of description to describe one element or feature's relationship to another element(s) or feature(s) as illustrated in the Figures. It will be understood that the spatially relative terms are intended to encompass different orientations of a device in use or operation in addition to the orientation depicted in the figures. For example, if the device in the Figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

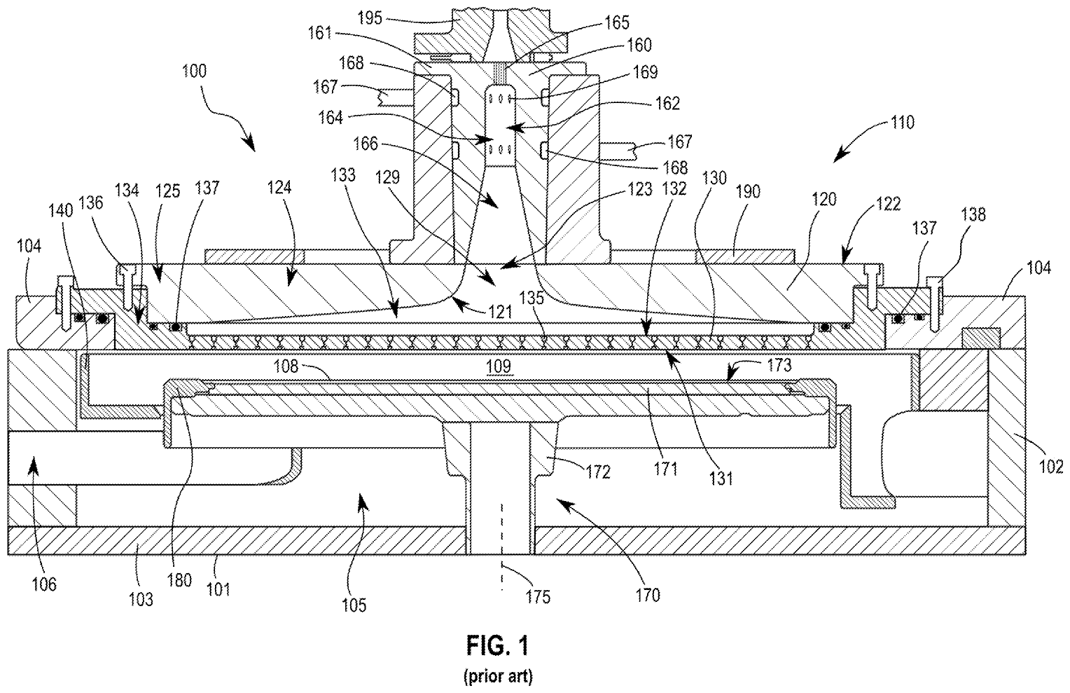

FIG. 1 illustrates a prior art embodiment of a semiconductor manufacturing processing chamber 100. The semiconductor manufacturing processing chamber 100 comprises a chamber body 101 having sidewalls 102 and a bottom 103 surrounding a interior volume 105. The sidewall 102 and bottom 103 can be integrally formed or separate component connected together by any suitable connection or fastener known to the skilled artisan. In some embodiments, the chamber body 101 includes a lid plate 104. The lid plate 104 can be permanently connected to the sidewall 102, or a separate component that is attached to the sidewall 102 by any suitable connection known to the skilled artisan.

The semiconductor manufacturing processing chambers 100 of some embodiments includes a gas distribution assembly 110. The gas distribution assembly 110 comprises a backing plate 120 and a showerhead 130.

Chamber body 101, in conjunction with the gas distribution assembly 110 encloses the interior volume 105 of the semiconductor manufacturing processing chamber 100. During processing, the interior volume 105 of the semiconductor manufacturing processing chamber 100 is typically maintained at a controlled pressure (usually a low-pressure environment) using one or more gas inlet (not shown) and one or more exhaust 106. The exhaust 106 is illustrated as part of the sidewall 102. However, the skilled artisan will recognize that the exhaust 106 can be located in any suitable. The skilled artisan will be familiar with the general construction of the chamber body 101 and the use of gas inlets and exhaust systems.

The backing plate 120 has a front surface 121 and a back surface 122 that define a thickness of the backing plate 120. The backing plate 120 has an inner portion 124 and an outer portion 125. The backing plate 120 contacts the showerhead 130 at the outer portion 125.

The backing plate 120 has an inlet opening 123 in a center thereof. The inlet opening 123 extends through the thickness of the backing plate 120 from the back surface 122 to the front surface 121. The central axis of the backing plate 120 is defined at the center of the inlet opening 123. The outer peripheral edge of the inner portion 124 of the front surface 121 is concentric with the inlet opening 123. While the backing plate 120 of some embodiments has an oblong or non-symmetrical shape, the central axis is considered to be at the center of the inlet opening 123 even if that is not the center of mass of the backing plate 120.

The front surface 121 of the backing plate 120 at the inner portion 124 has a concave shape. The concave shape of some embodiments has a linear slope from the inlet opening 123 to the outer peripheral edge of the inner portion 124 at the transition to the outer portion 125. In some embodiments, as shown in FIG. 1, the concave shape has a curved profile from the inlet opening 123 to the outer peripheral edge of the inner portion 124.

The gas distribution assembly 110 includes a showerhead 130, which may also be referred to as a “showerhead”. The showerhead 130 has a front surface 131 and a back surface 132 defining a thickness of the showerhead 130. The showerhead 130 has an inner portion 133 and an outer portion 134. The inner portion 133 of the showerhead 130 aligns with the inner portion 124 of the backing plate 120 and the outer portion 134 of the showerhead 130 aligns with the outer portion 125 of the backing plate 120. The inner portion 133 of the showerhead 130 comprises a plurality of apertures 135 extending through the thickness of the showerhead 130.

The backing plate 120 can be connected to the showerhead 130 by any suitable connection known to the skilled artisan. For example, the backing plate 120 can be welded to the showerhead 130. In some embodiments, as illustrated in FIG. 1, the backing plate 120 is connected to the showerhead 130 with a plurality of fasteners 136. In some embodiments, the showerhead 130 is connected to the lid plate 104 using a plurality of fasteners 138. Suitable fasteners include, but are not limited to, bolts, and can be used with or without O-rings 137.

When the front surface 121 of the outer portion 125 of the backing plate 120 is in contact with the outer portion 134 of the back surface 132 of the showerhead 130, a gas box plenum 129 is formed in the space between the front surface 121 of the inner portion 124 of the backing plate 120 and the inner portion 133 of the back surface 132 of the showerhead 130.

In some embodiments, the gas box plenum 129 has a coating to improve chemical compatibility. In some embodiments, the coating covers the entire front surface 121 of the backing plate 120 and the entire back surface 132 of the showerhead 130, including in the inlet opening 123 of the backing plate 120 and the plurality of apertures 135 of the showerhead 130. In some embodiments, the coating is only on the portions of the backing plate 120 and showerhead 130 that will come into contact with the process gases.

In some embodiments, the gas distribution assembly 110 further comprises a cap housing 150 connected to the back surface 122 of the backing plate 120. The cap housing 150 has a gas insert 160 with an inner channel 162 aligned with the opening 123 in the center of the backing plate 120. The inner channel 162 of some embodiments has an upper portion 164 and a lower portion 166. The upper portion 164 has a larger inner diameter than the inner diameter of the lower portion 166.

In use, one or more gases flow through inlets 167 into a plenum 168 formed between an inner surface of the cap housing 150 and an outer surface of the gas insert 160. A plurality of apertures 169 form a fluid connect between the plenum 168 and the inner channel 162.

In some embodiments, the processing chamber 100 further comprises a pumping ring 140 within the interior volume 105. In some embodiments, the pumping ring 140 is positioned on a top surface of a choke plate (not shown) which is positioned on the sidewall 102 of the chamber body 101 of the semiconductor manufacturing processing chamber 100. The pumping ring 140 has a front surface and a back surface defining a thickness of the pumping ring 140. In use, the back surface of the pumping ring 140 is positioned adjacent to or in contact with the front surface 131 of the showerhead 130. In some embodiments, in use, the front surface of the pumping ring 140 is positioned in contact with the top surface of the choke plate.

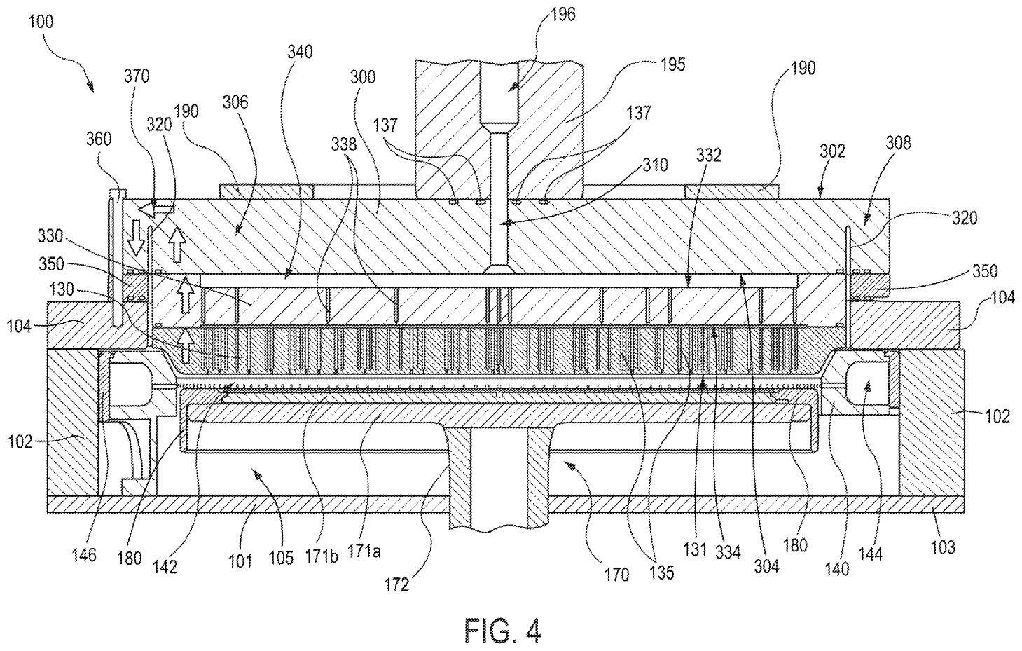

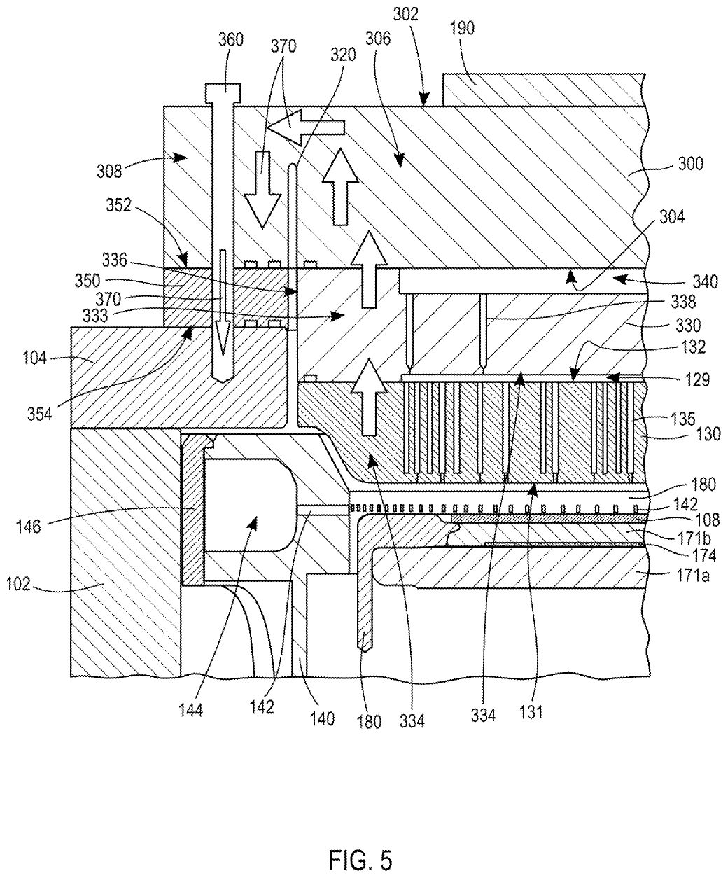

Referring to FIGS. 4 and 5, the pumping ring 140 of some embodiments comprises a plurality of openings 142 that form a fluid connection between the process gap 109 and an exhaust plenum 144. In some embodiments, the pumping ring 140 includes an outer wall 146 that forms the exhaust plenum 144.

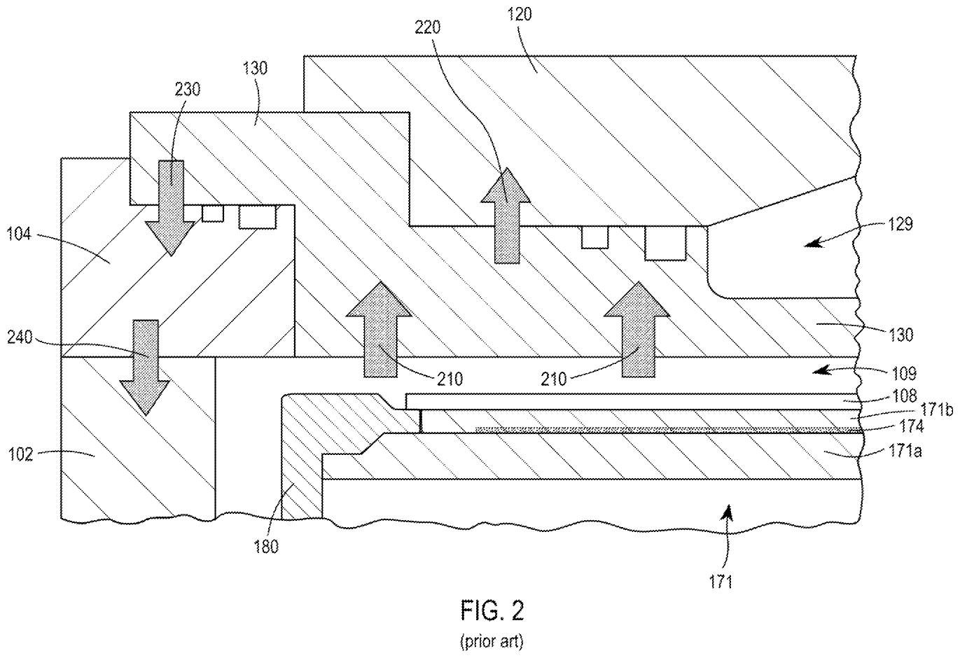

Referring again to FIGS. 1 and 2, the semiconductor manufacturing processing chamber 100 comprises a substrate support 170 within the interior volume 105. The substrate support 170 of some embodiments comprises a support body 171 positioned on a support shaft 172. The support body 171 has a support surface 173 configured to support a semiconductor wafer 108 for processing.

The support shaft 172 of some embodiments is configured to move the support body 171 closer to/further from the showerhead 130 and/or around a rotational axis 175 of the support shaft 172. During processing, the support surface 173 is spaced from the front surface 131 of the showerhead 130 to form a process gap 109. While not shown, the skilled artisan will understand that rotational and translational movement of the substrate support 170 can be driven by any suitable mechanism including, but not limited to, motors and actuators.

In some embodiments, the support body 171 includes a thermal element (not shown) configured to heat the semiconductor wafer 108 on the support surface 173. The thermal element can be any suitable heating mechanism known to the skilled artisan. For example, in some embodiments, the thermal element comprises a resistive heating element that is connected to a power supply (not shown) configured to apply power to the thermal element to heat the support body 171. In some embodiments, the support body 171 includes an electrostatic chuck (ESC) (not shown). The skilled artisan will be familiar with the construction of the ESC and the manner in which the ESC is powered and employed.

In some embodiments, as shown in FIG. 1, the support surface 173 comprises more than one component. For example, the illustrated embodiment has two components connected together by any suitable connection (e.g., brazing or welding). Use of multiple components may allow for easier assembly of the thermal elements or electrostatic chuck components which can be located between the and enclosed by the support body components.

In some embodiments, the support body 171 is surrounded by an edge ring 180. The edge ring 180 aids in centering of the semiconductor wafer 108 during processing and also helps to direct gas flows around the edge of the semiconductor wafer 108 to prevent backside deposition or other unwanted reactions on the back of the semiconductor wafer 108 or the support surface 173 of the support body 171.

Some embodiments of the gas distribution assembly 110 include a heater assembly 190 positioned adjacent the back surface 122 of the backing plate 120. The heater assembly 190 can include any suitable heater known to the skilled artisan. For example, the heater assembly 190 of some embodiments comprises a resistive heater which is connected to a power source and/or controller (not shown).

In some embodiments, the gas insert 160 includes one or more opening 165 in the top wall 161 of the gas insert 160. The one or more opening 165 can be configured to allow a flow of gas, either a reactive or inert gas, into the inner channel 162. For example, in some embodiments, a remote plasma source (RPS) (not shown) is connected to the gas insert 160 through a cooling flange 195. The cooling flange 195 is configured to allow a gas to flow through the cooling flange 195 toward the gas insert 160 while a cooling fluid is flowed through at least a portion of the cooling flange 195 to prevent elevated temperatures from the RPS from impacting the gas insert 160 or other chamber components.

FIG. 2 shows a portion of the semiconductor manufacturing processing chamber 100 of FIG. 1 where the gas distribution assembly 110, lid plate 104 and sidewall 102 meet. In operation, the showerhead (showerhead 130) is primarily heated by radiative transfer 210 from the substrate support 170, as illustrated in FIG. 2. For example, the support body 171 in the illustrated embodiment comprises a lower support body plate 171a and an upper support body plate 171b with a heating element 174 therebetween. The lower support body plate 171a and upper support body plate 171b can be connected together by any suitable means known to the skilled artisan. The individual thicknesses, or relative thicknesses, of the lower support body plate 171a and upper support body plate 171b are exemplary only and should not be taken as limiting the scope of the disclosure. For descriptive purposes, the general directions of heat dissipation from the showerhead 130 is illustrated with large arrows.

Current process chambers have little to no control on the thermal distribution through the thermal base and showerhead (showerhead). The heat dissipation from the showerhead (showerhead 130) is non-directional, flowing into the funnel (backing plate 120) via arrow 220 and the chamber sidewall 102 through the lid plate 104, as illustrated by arrow 240 and arrow 230, respectively. The rate of the heat dissipation through the available routes can differ due to, for example, the contact area of the components and temperature differentials between the components.

Accordingly, one or more embodiments of the disclosure are directed to gas distribution assemblies comprising a showerhead (showerhead), backer plates and/or thermal bases with a controlled thermal dissipation pathway. Some embodiments are directed to processing chambers using the showerhead (showerhead), backer plates and/or thermal bases.

In some embodiments, the gas distribution assembly comprises a thermal base, a blocker plate and a showerhead (showerhead) arranged to thermally isolate the components to drive the thermal dissipation pathway through an outer edge of the thermal base by a tortuous pathway.

Some embodiments of the disclosure improve the thermal uniformity of the showerhead (showerhead) by controlling the pathway for the dissipation of heat from the showerhead (showerhead), creating a smaller contact area which forms a restriction to the heat flow.

Some embodiments of the disclosure provide novel solutions to improve thermal non-uniformity, temperature floating of the showerhead (showerhead), and high temperature applications for processing semiconductors by directional heat conductivity for CVD/ALD processes.

Some embodiments of the disclosure provide a longer thermal loss pathway, leading to improved temperature uniformity and a more symmetric heat loss around the lid. In some embodiments, the thermal uniformity of the showerhead (showerhead) is less than 3%. In some embodiments, a thicker base plate and showerhead (showerhead) improve thermal uniformity and decrease thermal deformation.

Some embodiments use dual seals and/or differential pumping to increase the process temperature window (up to 300° C.). Some embodiments show good thermal steadiness with improved repeatability and uniform thermal capacitance.

In some embodiments, the blocker plate is used to improve thermal flow and deformation which minimizes temperature fluctuations. Lid design with a new thermal path is channeled to minimize the heat loss/floating issue. Additionally, dual seals and differential pumping may be included to allow for high temperature applications. Some embodiments show decreased deformation which helps uniform gas distribution all over the surface of the wafer. In some embodiments, a thicker blocker plate and showerhead (showerhead) are incorporated to increase bow resistance due to heating.

In some embodiments, the baseplate acts as a thermal cushion for the showerhead (showerhead) and thermal base to overcome extreme temperature differentials. In some embodiments, the addition of the baseplate increases uniform distribution of gases to the showerhead (showerhead) and onto the wafer surface. Some embodiments improve control of the gas distribution with a plenum between the showerhead (showerhead) and baseplate, and between the baseplate and thermal base. Some embodiments of the disclosure advantageously allow for tunability of the temperature and gas flows by controlling the blocker plate hole sizes and by controlled plenum volume. Some embodiments eliminate the need for a mechanical mixer for composition uniformity.

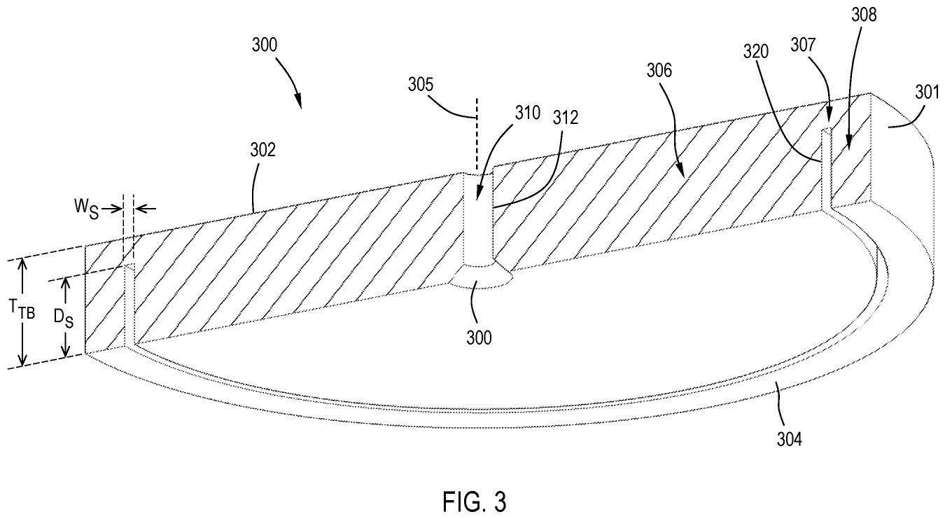

With reference to FIGS. 3 through 5, one or more embodiments of the disclosure are directed to a thermal base 300 for a gas distribution assembly 110. FIG. 3 illustrates a bottom isometric cross-section view of a thermal base 300 according to one or more embodiments of the disclosure. The thermal base of some embodiments is configured to attenuate thermal transfer from the inner portion to the outer portion of the thermal base and to maintain thermal uniformity of the gas distribution assembly.

The thermal base 300 comprises a back surface 302 and a front surface 304 that define a thickness T_{TB} of the thermal base 300. The front surface 304 of the thermal base 300 has an inner portion 306 and an outer portion 308. The thermal base 300 of some embodiments is a disc-shaped body with an outer peripheral face 301. In some embodiments, the thermal base 300 is an asymmetrical shape.

The thermal base 300 includes an opening 310 extending through the thickness T_{TB} thereof. The central axis 305 of the thermal base 300 is centered at the opening 310, even if the opening 310 is not in the center of mass of the 300. The opening 310 of some embodiments is a cylindrical opening. As used in this manner, a cylindrical opening has a cylindrical shape that extends through at least half of the thickness T_{TB} of the thermal base 300. For example, the embodiment illustrated in FIG. 3 has a cylindrical opening 310 because the cylindrical portion 312 extends from the back surface 302 to more than 50% of the thickness T_{TB}. At the proximal end of the cylindrical portion 312, the opening 310 flares outwardly to create a flared portion 314 in which the opening 310 in the front surface 302 of the thermal base 300 is wider (i.e., a larger diameter) than at the front surface 304. The shape of the flared portion 314 can be any suitable shape. For example, the flared portion 314 of some embodiments has a linear, concave or convex profile.

The thermal base 300 includes an annular slit 320 formed in the front surface 304 of the thermal base 300. The annular slit 320 forms a boundary between the inner portion 306 and the outer portion 308 of the thermal base 300. The annular slit 320 having a width W_{S} and depth D_{S} measured from the front surface 304 of the thermal base 300.

The width W_{S} and depth D_{S} of the annular slit 320 can affect the rate of thermal transfer through the thermal base 300. The annular slit 320 of some embodiments has a width W_{S} sufficient to prevent or minimize thermal conduction across from the inner portion 306 to the outer portion 308 across the width W_{S}. In some embodiments, the width W_{S} of the 320 is sufficiently large to ensure that thermal conduction from the inner portion 306 to the outer portion 308 passes through the bridge portion 307 of the thermal base 300. The bridge portion 307 is the portion of the meat of the thermal base 300 between the back surface 302 and the bottom edge of the annular slit 320. In some embodiments, the width W_{S} of the annular slit 320 is greater than or equal to 1 mm, 1.5 mm, 2 mm, 2.5 mm or 3 mm.

The annular slit 320 of some embodiments has a depth D_{S} in the range of 50% to 90% of the thickness T_{TB} of the thermal base 300. The depth D_{S} is measured from the front surface 304 of the thermal base 300. In some embodiments, the depth D_{S} of the annular slit 320 is greater than or equal to 25%, 30%, 35%, 40%, 45%, 50%, 55%, 60%, 65%, 70% or 75% and less than or equal to 95%, 90% or 85% of the thickness T_{TB} of the thermal base 300.

The depth DS of the annular slit 320 depends on the thickness T_{TB} of the thermal base 300. In some embodiments, the thermal base 300 has a thickness T_{TB} in the range of 1.25″ to 2″.

The material that the thermal base 300 is made of can impact the thermal conductance from the inner portion 306 to the outer portion 308. In some embodiments, the thermal base 300 comprises a thermally conductive material. Suitable thermally conductive materials include, but are not limited to aluminum, stainless steel, titanium nitride.

The inner diameter ID of the annular slit 320 can be any suitable diameter depending on, for example, the diameter of the wafers to be processed in the processing chamber. In some embodiments, the annular slit 320 has an inner diameter ID greater than or equal to 300 mm.

Some embodiments of the disclosure are directed to gas distribution assemblies 110 for a semiconductor manufacturing processing chamber 100. FIG. 4 shows a cross-sectional view of a semiconductor manufacturing processing chamber 100 according to one or more embodiments of the disclosure. FIG. 5 shows an expanded view of a portion of the semiconductor manufacturing processing chamber 100 of FIG. 4. Reference numerals described above with respect to FIGS. 1 and 2 are reused in FIGS. 4 and 5 for comparable components.

The gas distribution assembly 110 of some embodiments has a thermal base 300, a blocker plate 330 and a showerhead 130. The blocker plate 330 has a back surface 332 and a front surface 334 defining a thickness T_{BP} of the blocker plate 330. The blocker plate 330 is positioned so that an outer portion of the back surface 332 contacts the inner portion 306 of the thermal base 300. The blocker plate 330 has a plurality of apertures 338 extending through the thickness T_{BP} thereof.

A plenum 340 is formed between the thermal base 300 and the blocker plate 330 so that a gas flowing through the opening 310 disperses throughout the plenum 340 before passing through the plurality of apertures 338.

A showerhead 130 is positioned so that an outer portion 134 of the back surface 132 of the showerhead 130 contacts an outer portion 333 of the front surface 334 of the blocker plate 330.

An insulator plate 350 is positioned around an outer peripheral edge 336 of the blocker plate 330. The insulator plate 350 prevents or minimizes thermal conduction between the thermal base 300 and the showerhead 130 of lid plate 104. The insulator plate 350 has a back surface 352 and a front surface 354 defining a thickness of the insulator plate 350. The back surface 352 of the insulator plate 350 is in contact with the outer portion 308 of the front surface 304 of the thermal base 300. The inner diameter face of the 350 of some embodiments is spaced a distance from the outer peripheral edge 336 of the blocker plate 330 that is equal to or greater than the width of the annular slit 320. The front surface 354 of the insulator plate 350 of some embodiments, as shown in the Figures, is in contact with the lid plate 104 of the semiconductor manufacturing processing chamber 100.

The gas distribution assembly 110 of some embodiments comprises at least one thermal contact 360 extending through the thickness T_{TB} of the outer portion 308 of the thermal base 300 and extending through the thickness of the insulator plate 350. In some embodiments, the thermal contact 360 projects from the front surface 354 of the insulator plate 350. The at least one thermal contact 360 can be made of any suitable material that can conduct thermal energy from the thermal base 300 to the lid plate 104. In some embodiments, the at least one thermal contact 360 comprises steel, stainless steel, aluminum or other conductive material. In some embodiments, the at least one thermal contact 360 acts as a fastener to connect the thermal base 300 and insulator plate 350 to the lid plate 104.

In some embodiments, the outer peripheral edge 336 of the blocker plate 330 is aligned with the inner diameter of the annular slit 320 of the thermal base 300, and the inner diameter face of the insulator plate 350 is aligned with the outer diameter of the annular slit 320 of the thermal base 300.

Additional embodiments of the disclosure are directed to semiconductor manufacturing processing chamber 100 comprising the gas distribution assembly 110 with thermal base 300 as described herein. The annular slit 320 is sized to prevent radiative heat transfer from the showerhead 130 to the lid plate 104.

In the embodiment illustrated in FIG. 4, a cooling flange 195 is connected to the thermal base 300 so that the channel 196 in the cooling flange 195 is aligned with the opening 310 of the thermal base 300.

Further embodiments of the disclosure are directed to processing methods comprising heating a substrate support 170 positioned within an interior volume 105 of a semiconductor manufacturing processing chamber 100 to a temperature greater than standard room temperature (25° C.). The substrate support 170 heats a showerhead 130 positioned adjacent to and spaced from the substrate support 170. The method comprises preventing radiative heat transfer from the showerhead 130 to the lid plate 104 of the semiconductor manufacturing processing chamber 100.

In some embodiments of the method, preventing radiative heat transfer from the showerhead 130 directly to the lid plate 104 causes thermal transfer from the showerhead 130 through a thermal base 300 and at least one thermal contact 360 to the lid plate 104. In some embodiments, preventing radiative heat transfer from the showerhead 130 directly to the lid plate 104 improves thermal uniformity of the showerhead 130 by increasing thermal path length. Referring to FIGS. 4 and 5, the thermal path 370 is illustrated using arrows to show the movement of heat from the showerhead 130 through the blocker plate 330 and into the thermal base 300. In the thermal base 300, the heat flows from the inner portion 306 to the outer portion 308 across the bridge portion 307 formed by the annular slit 320. Heat then flows through the at least one thermal contact 360 to pass through the insulator plate 350 into the lid plate 104. In some embodiments, the thermal path 370 is configured to attenuate thermal transfer from the inner portion to the outer portion and maintain thermal uniformity in the gas distribution assembly or showerhead 130.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A thermal base for a gas distribution assembly, the thermal base comprising:
back surface and a front surface defining a thickness of the thermal base, the front surface having an inner portion and an outer portion;
a cylindrical opening extending through the thickness of the thermal base; and
an annular slit formed in the front surface of the thermal base, the annular slit forming a boundary between the inner portion and outer portion, the annular slit having a width and depth measured from the front surface,
wherein the thermal base is configured to attenuate thermal transfer from the inner portion to the outer portion and maintain thermal uniformity in the gas distribution assembly.

2. The thermal base of claim 1, wherein the annular slit has a width greater than or equal to 1 mm.

3. The thermal base of claim 1, wherein the annular slit has a depth in a range of 50% to 90% of the thickness of the thermal base, measured from the front surface of the thermal base.

4. The thermal base of claim 1, wherein the thickness of the thermal base is in a range of 1.25″ to 2″.

5. The thermal base of claim 1, wherein the thermal base comprises aluminum.

6. The thermal base of claim 1, wherein the annular slit has an inner diameter greater than or equal to 300 mm.

7. A gas distribution assembly for a semiconductor manufacturing processing chamber, the gas distribution assembly comprising:
a thermal base having a back surface and a front surface defining a thickness of the thermal base, the front surface having an inner portion and an outer portion, a cylindrical opening extending through the thickness of the thermal base, and an annular slit formed in the front surface of the thermal base, the annular slit forming a boundary between the inner portion and outer portion, the annular slit having a width and depth measured from the front surface;
a blocker plate having a back surface and a front surface defining a thickness of the blocker plate, the blocker plate positioned so that an outer portion of the back surface of the blocker plate contacts the inner portion of the front surface of the thermal base, the blocker plate having a plurality of apertures extending through the thickness of the blocker plate;
a showerhead having a back surface and a front surface defining a thickness of the showerhead, the showerhead positioned so that an outer portion of the back surface of the showerhead contacts an outer portion of the front surface of the blocker plate;
an insulator plate around an outer peripheral edge of the blocker plate, the insulator plate having a back surface in contact with the outer portion of the front surface of the thermal base; and
at least one thermal contact extending through the thickness of the outer portion of the thermal base and extending through the thickness of the insulator plate.

8. The gas distribution assembly of claim 7, wherein the annular slit has a width greater than or equal to 1 mm.

9. The gas distribution assembly of claim 7, wherein the annular slit has a depth in a range of 50% to 90% of the thickness of the thermal base, measured from the front surface of the thermal base.

10. The gas distribution assembly of claim 7, wherein the thickness of the thermal base is in a range of 1.25″ to 2″.

11. The gas distribution assembly of claim 7, wherein the thermal base comprises aluminum.

12. The gas distribution assembly of claim 7, wherein the annular slit has an inner diameter greater than or equal to 300 mm.

13. The gas distribution assembly of claim 12, wherein the outer peripheral edge of the blocker plate is aligned with the inner diameter of the annular slit of the thermal base.

14. A semiconductor manufacturing processing chamber comprising:
a chamber body having at least one sidewall;
a lid plate on the at least one sidewall of the chamber body, the chamber body and lid plate enclosing an interior volume of the processing chamber, the lid plate comprising an opening extending through a thickness of the lid plate; and
the gas distribution assembly of claim 7 positioned within the opening in the lid plate, the blocker plate and showerhead spaced a distance from an inner diameter face of the opening greater than or equal to 1 mm to prevent radiative heat transfer from the showerhead or blocker plate to the lid plate.

15. The semiconductor manufacturing processing chamber of claim 14, wherein the at least one thermal contact projects from a front surface of the insulator plate and extends a distance into a thickness of the lid plate.

16. The semiconductor manufacturing processing chamber of claim 15, wherein the at least one thermal contact acts as a fastener to connect the thermal base and insulator plate to the lid plate.

17. The semiconductor manufacturing processing chamber of claim 15, further comprising a substrate support pedestal within the interior volume of the processing chamber, the substrate support pedestal comprising a support shaft with a support base thereon, the support base having a support surface configured to support a substrate during processing, the support base comprising a thermal element configured to control a temperature of the support base.

18. A processing method comprising:
heating a substrate support pedestal positioned within an interior volume of a semiconductor manufacturing processing chamber to a temperature greater than standard room temperature, the substrate support pedestal heating a showerhead positioned adjacent to and spaced from the substrate support pedestal, and
preventing radiative heat transfer from the showerhead to a lid plate of the processing chamber.

19. The processing method of claim 18, wherein preventing radiative heat transfer from the showerhead directly to the lid plate causes thermal transfer from the showerhead through a thermal base and at least one thermal contact to the lid plate, the thermal base having a back surface and a front surface defining a thickness of the thermal base, the front surface having an inner portion and an outer portion, a cylindrical opening extending through the thickness of the thermal base, and an annular slit formed in the front surface of the thermal base, the annular slit forming a boundary between the inner portion and outer portion, the annular slit having a width and depth measured from the front surface, the at least one thermal contact extending through the thickness of the outer portion of the thermal base and a distance into a thickness of the lid plate.

20. The processing method of claim 19, wherein preventing radiative heat transfer from the showerhead directly to the lid plate improves thermal uniformity of the showerhead by increasing thermal path length.
